(19) United States
(12) Patent Application Publication
(10) Pub. No.: US 2008/0036048 A1
(43) Pub. Date: Feb. 14, 2008

(54) Semiconductor junction device having reduced leakage current and method of forming same

(75) Inventors: Sheng-Huei Dai, Hsinchu (TW); Ya-Chin King, Hsinchu (TW); Hai-Ning Wang, Hsin Tien (TW); Ming-Tai Chiang, Hsin Tien (TW)

Correspondence Address: MAYER & WILLIAMS PC, 251 NORTH AVENUE WEST, 2ND FLOOR, WESTFIELD, NJ, 07090, US

(73) Assignee: Vishay General Semiconductor LLC

(21) Appl. No.: 11/827,594

(22) Filed: Jul. 12, 2007

Related U.S. Application Data
(60) Provisional application No. 60/836,874, filed on Aug. 10, 2006.

(51) Int. Cl. H01L 21/76; H01L 29/12

(52) U.S. Cl. 257/656; 438/449; 257/E21.54; 257/E29.211

(57) ABSTRACT

A semiconductor junction device includes a semiconductor substrate of a first conductivity type and a junction layer formed on the substrate which has a second conductivity type. A field reducing region of the first conductivity type surrounds a periphery of the junction layer and extends under a peripheral portion of the junction layer. An insulating layer is provided on the field reducing region and a metal layer overlies the junction layer and the insulating layer.

### STATEMENT OF RELATED APPLICATION

This application claims the benefit of U.S. Provisional Patent Application Ser. No. 60/836,874, filed Aug. 10, 2006, entitled “LOCOS Application in Low Voltage TVS”, which is incorporated by reference in its entirety herein.

### FIELD OF THE INVENTION

The present invention relates generally to semiconductor junction devices such as transient voltage suppressors, and in particular to a semiconductor junction device in which the oxide layers are formed by a LOCOS process.

### BACKGROUND OF THE INVENTION

Communications equipment, computers, home stereo amplifiers, televisions, and other electronic devices are increasingly manufactured using small electronic components which are very vulnerable to damage from electrical energy surges (i.e., transient over-voltages). Surge variations in power and transmission line voltages, can severely damage and/or destroy electronic devices. Moreover, these electronic devices can be very expensive to repair and replace. Therefore, a cost effective way to protect these components from power surges is needed. Devices known as transient voltage suppressors (TVS) have been developed to protect these types of equipment from such power surges or over-voltage transients. These devices, typically discrete devices similar to discrete voltage-reference diodes, are employed to suppress transients of high voltage in a power supply or the like before the transients reach and potentially damage an integrated circuit or similar structure.

One type of semiconductor junction device that may be employed as a TVS is a P/N junction device which operates like a diode, conducting current in one direction (from the metal anode to the semiconductor cathode) and functioning as an open-circuit in the opposite direction. Such diodes are widely used in electronic systems such as amplifiers, receivers, control and guidance systems, power and signal monitors, and as rectifiers and clamps in RF circuits. Commercial applications include radiation detectors, imaging devices, and wired and wireless communications products. High frequency diodes may be GaAs devices, and frequently are discrete devices.

P/N junction diodes often have poor reverse leakage and poor breakdown characteristics. To improve leakage characteristics, high performance Schottky diodes are provided with junction field reducing regions. Field reducing regions provide excellent breakdown characteristics in both forward and reverse bias. FIG. 1 shows a conventional semiconductor junction device that may be used as a transient voltage suppressor for low voltage applications. The diode includes a p+ doped semiconductor substrate 102 and a P-epi-layer 104 that is formed on the substrate 102 by a blanket ion implantation process. A junction is formed between an n+ junction layer 108 and metal layer 110. Field oxide regions 206 surround the junction. The p-epi layer 104, which serves as a field reducing region, underlies the field oxide regions 206 and also surrounds the n+ junction layer 108.

One problem with the aforementioned conventional device is that while the field reducing region 104 can reduce the electric field that arises at the sharp corners defined by the n+ junction 108 and the oxide 106, there nevertheless may remain a small region near the oxide 106 at the interface between n+ junction layer 108 and the p+ substrate 102 (i.e., the region denoted 130 in FIG. 1) which is not surrounded by the field reducing region. The resulting electric field could give rise to an excessive leakage current in that region.

Another problem with the conventional semiconductor junction device shown above is that its fabrication may require at least two or more photo masks. Thus, an object of the present method is to reduce the leakage current and simplify the fabrication process.

### SUMMARY OF THE INVENTION

In accordance with the present invention, a semiconductor junction device is provided. The device includes a semiconductor substrate of a first conductivity type and a junction layer formed on the substrate which has a second conductivity type. A field reducing region of the first conductivity type surrounds a periphery of the junction layer and extends under a peripheral portion of the junction layer. An insulating layer is provided on the field reducing region and a metal layer overlies the junction layer and the insulating layer.

In accordance with one aspect of the invention, the field reducing region is more lightly doped than the semiconductor substrate.

In accordance with another aspect of the invention, the first conductivity type is p-type.

In accordance with another aspect of the invention, the insulating layer is an oxide layer.

In accordance with another aspect of the invention, the insulating layer is a LOCOS layer.

In accordance with another aspect of the invention, the insulating layer includes a PAD oxide sub-layer.

In accordance with another aspect of the invention, the junction layer is an epitaxial layer.

In accordance with another aspect of the invention, a method of forming a semiconductor device is provided. The method begins by forming a first layer of a first conductivity type on a substrate of a first conductivity type, wherein the first layer is more lightly doped than the substrate. A LOCOS region is formed. The LOCOS region surrounds an exposed portion of the first layer to define a junction region. Ions of a second conductivity type are implanted into the junction region so that the junction region has a second conductivity. A metal layer is formed over the LOCOS region and the junction region.

### BRIEF DESCRIPTION OF THE DRAWINGS

FIG. 1 shows a conventional semiconductor junction device that may be used as a transient voltage suppressor for low voltage applications.

FIG. 2 is a cross-sectional view showing an p+ doped semiconductor substrate on which the junction device will be formed.

FIG. 3 shows a p− epi layer that is formed on the substrate.

FIG. 4 shows a PAD oxide layer is formed on the p− epi layer of FIG. 3.

FIG. 5 shows a nitride layer formed on the PAD oxide layer.

FIG. 6 shows a photoresist pattern coated on the nitride layer to define a region in which an interface will be formed.

FIG. 7 shows the nitride layer and the PAD oxide layer after they have been etched.

FIG. 8 shows the device after the nitride layer has been removed and the field oxide formed.

FIG. 9 shows implantation of n-type impurities into the portion of the oxide and the P+ substrate in which the interface is to be formed.

FIG. 10 shows a metal barrier layer formed on the oxide and the interface region.

FIGS. 11 and 12 show the results of a simulation performed on a conventional semiconductor junction device and a semiconductor junction device in accordance with the present invention, respectively.

### DETAILED DESCRIPTION

The present inventors have recognized that by altering the manner in which the oxide layer of a semiconductor junction device is formed, the field reducing region located below the field oxide regions can be arranged so that it surrounds the corner of the n+/p+ interface, thereby reducing the leakage current that arises. In particular, the inventors have determined that a local oxidation of silicon (LOCOS) process can be used to form the oxide layer. LOCOS processes are widely used for device isolation applications in the semiconductor industry. In LOCOS processes, a thin layer of silicon oxide (SiO₂) is initially grown over the wafer or substrate surface. This thin oxide layer is often referred to as a pad oxide and functions for inhibiting the transition of stresses between the silicon substrate and the subsequently deposited nitride layer. Following this, a layer of silicon nitride is deposited on top of the pad oxide layer and lithographically defined to form an oxidation mask over the active device regions of the wafer. The nitride layer prevents the oxidation of active areas during the isolation oxide growth. The nitride layer is etched from the area between the active areas where an isolating SiO₂ layer, which is known as a field oxide, is to be thermally grown over the wafer. In a LOCOS process, the oxidation is generally performed in an oxidation furnace at a temperature range between about 800 C and 1100 C. At this temperature range, wafers are exposed to oxidizing species, such as oxygen or water steam, to grow the field oxides.

FIGS. 2-10 show one example of a process that may be employed to fabricate a semiconductor junction device in accordance with the present invention, which uses a LOCOS insulating region.

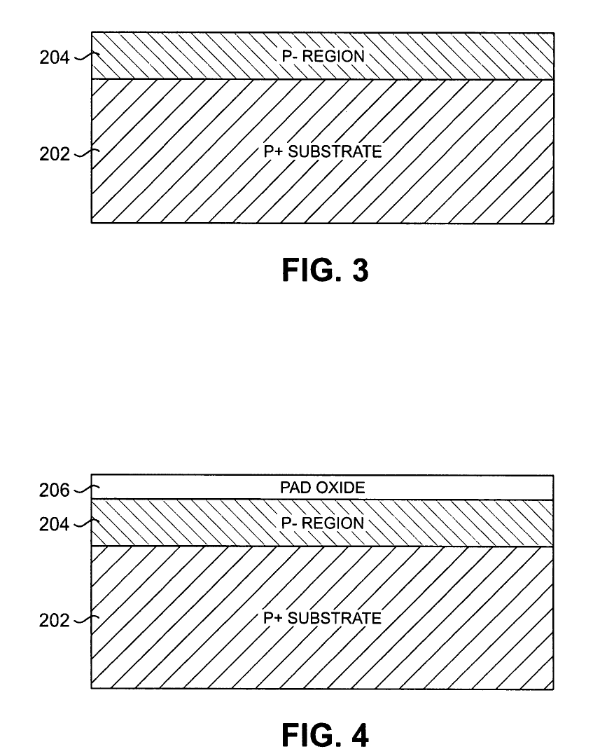

FIG. 2 is a cross-sectional view showing a p+ doped semiconductor substrate 202. In FIG. 3 a p-epi layer 204 is formed on the substrate 202 and will define the field reducing region. The p− epi layer 204 is formed in a blanket ion implantation process by implanting n-type ion species into the p+ substrate 202. The dosage and implant energy may be, respectively, from 0 (without implant) to 5×10¹⁴ cm² and 10-200 keV for an arsenic or phosphorus ion implant. Hence, the impurity concentration in the p+ doped substrate 202 is higher than that in the p− epi layer 204.

Next, in FIG. 4, a LOCOS process is begun in which a PAD oxide layer 206 is formed on the p− epi layer 204. PAD oxide layers are generally thermally grown oxides layers that are employed to separate adjacent layers on a substrate or wafer. As previously noted, in the context of a LOCOS process, a PAD oxide is a thin layer of silicon dioxide located beneath a layer of silicon nitride and above the silicon substrate. This layer of oxide serves as a pad or “buffer” to prevent the overlaying silicon nitride (which is in tension) form adversely affecting the silicon substrate. The PAD oxide layer 206 will generally range in thickness from 3000 to 10,000 angstroms.

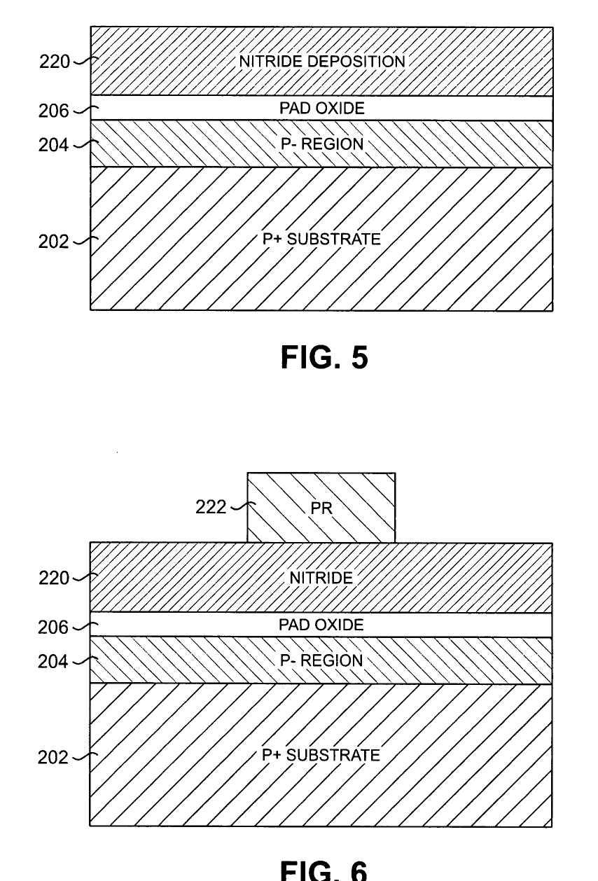

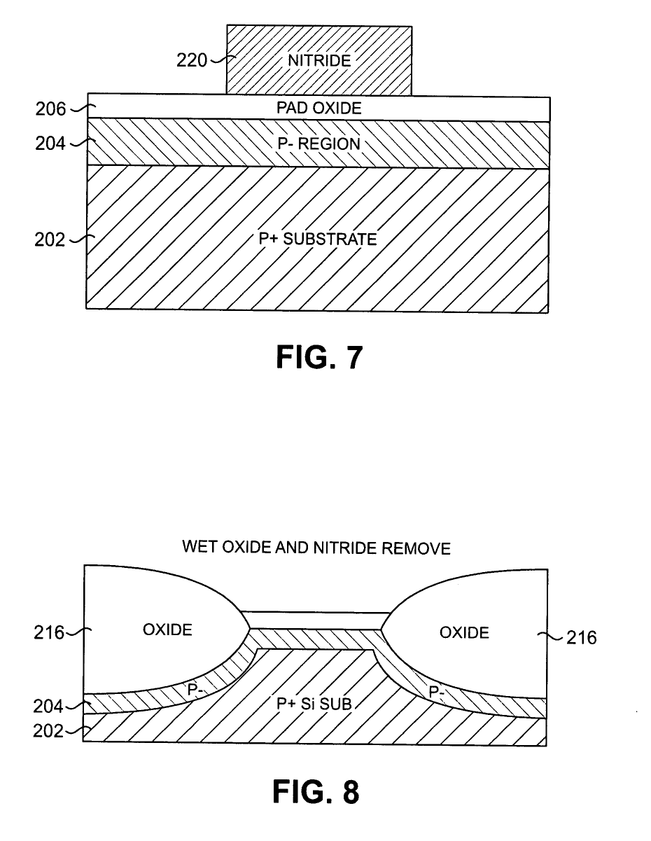

Referring to FIG. 5, the LOCOS process continues by depositing a nitride layer 220 on the PAD oxide layer 206. In FIG. 6, a photoresist pattern 222 is coated on the nitride layer 220 to define the region in which the Schottky interface will be formed. Subsequently, as shown in FIG. 7, an etch back step is performed to etch the nitride layer 220 by using the photoresist pattern 222 as a mask.

After the etch back step, the photoresist pattern 222 is stripped away and a thermal oxidation process is followed by using the nitride layer 220 as a mask, as is shown in FIGS. 7 and 8. During the thermal oxidation process, a pair of thick field oxide regions 216 are formed by using the nitride layer 220 as a mask. In addition, the ions in the p-region 204 and p+ substrate 202 are driven in both lateral and longitudinal directions into the substrate 202 and results in extending the regions thereof. The nitride layer 220 is then removed, as shown in FIG. 8.

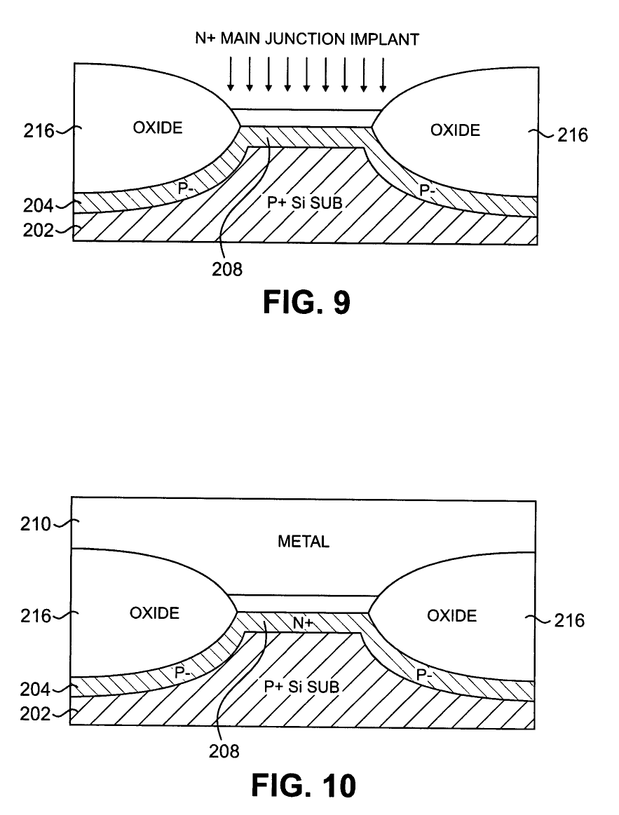

Referring to FIG. 9, an implant process is used to form an n+ junction layer 208 by implanting n-type impurities (e.g., phosphorus ions) into the portion of the oxide and the P+ substrate 202 in which the Schottky interface is to be formed. During this implant process the pad oxide 206 serves not only as a buffer layer between the silicon substrate 202 and the nitride layer 220, but also as a sacrificial oxide for ion implantation to prevent damage to the silicon substrate. After implantation, the pad oxide 206 is removed.

The dosage and implant energy may be about 1×10¹⁵ to 1×10¹⁶/cm² and 10-200 keV for arsenic or phosphorus ions. Finally, after implantation a refractory metal barrier layer 210 is deposited in FIG. 10. The refractory metal, can be, for instance, Ti, Ni, Cr, Mo, Pt, Zr, W etc., Subsequently, a top metal layer (not shown) overlies the Schottky barrier layer 210 and serves as an anode. A metal layer is also formed on the backside of substrate to function as a cathode electrode.

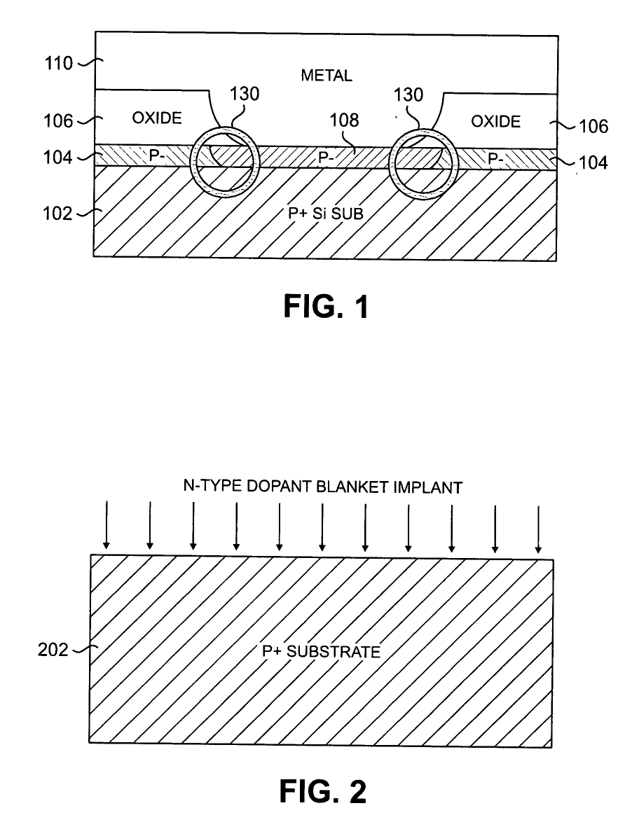

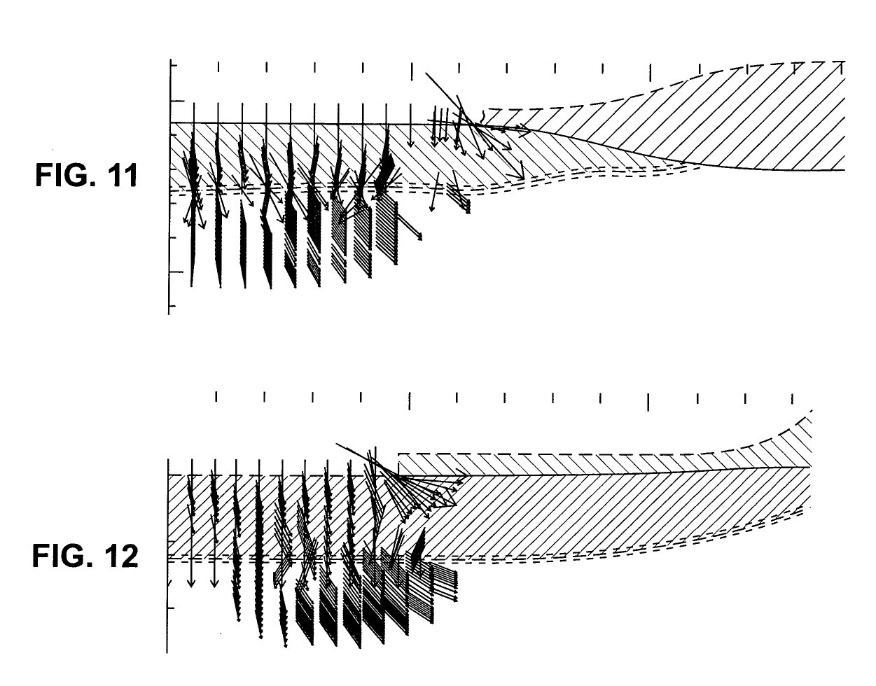

As seen in FIG. 10 the small region near the oxide 216 at the interface between the n+ junction layer 208 and the p+ substrate 202 is now surrounded by the field reducing region 204. Simulations have confirmed that the leakage current is reduced in the present invention in comparison to the conventional semiconductor junction device depicted in FIG. 1. For instance, FIG. 11 shows the current distribution at the corner of the junction in the conventional junction device. FIG. 12 shows the current distribution at the corner of the junction in the junction device of the present invention. As the figures indicate, the current density is more uniform in the present invention and thus the leakage current is suppressed.

Another advantage that arises from using a LOCOS process to fabricate the semiconductor junction device depicted above is that only a single photoresist mask is required. In contrast, when the conventional technique is employed two or more masks are generally required.

In the drawings and specification, there have been disclosed typical preferred embodiments of the invention and, although specific terms are employed, they are used in a generic and descriptive sense only and not for purposes of limitation, the scope of the invention being set forth in the following claims.

1. A semiconductor junction device, comprising:
a semiconductor substrate of a first conductivity type;
a junction layer formed on the substrate and having a second conductivity type;
a field reducing region of the first conductivity type surrounding a periphery of the junction layer and extending under a peripheral portion of the junction layer;
an insulating layer provided on the field reducing region; and
a metal layer overlying the junction layer and the insulating layer.

2. The semiconductor junction device of claim 1 wherein the field reducing region is more lightly doped than the semiconductor substrate.

3. The semiconductor junction device of claim 1 wherein the first conductivity type is p-type.

4. The semiconductor junction device of claim 1 wherein the insulating layer is an oxide layer.

5. The semiconductor junction device of claim 1 wherein the insulating layer is a LOCOS layer.

6. The semiconductor junction device of claim 1 wherein the insulating layer includes a PAD oxide sub-layer.

7. The semiconductor junction device of claim 1 wherein the junction layer is an epitaxial layer.

8. A method of forming a semiconductor device, comprising:
forming a first layer of a first conductivity type on a substrate of a first conductivity type, wherein the first layer is more lightly doped than the substrate;
forming a LOCOS region that surrounds an exposed portion of the first layer to define a junction region;
implanting ions of a second conductivity type into the junction region so that the junction region has a second conductivity; and
forming a metal layer over the LOCOS region and the junction region.

9. The semiconductor junction device of claim 8 wherein the first layer is an epitaxial layer.

10. The semiconductor junction device of claim 8 wherein the first layer is formed by implantation of ions of the first conductivity type into the substrate.

11. The method of claim 8 wherein formation of the LOCOS region comprises:
forming a PAD oxide over the first layer;
depositing a nitride layer over the PAD oxide;
patterning the nitride layer to define a junction region thereunder;
depositing a field oxide over exposed portions of the PAD oxide using the patterned nitride layer as a mask; and
removing the patterned nitride layer to expose the junction region.

12. A semiconductor diode, comprising:
a semiconductor substrate of a first conductivity type;
a first layer of the first conductivity type disposed on or in the substrate, wherein the first layer is more lightly doped than the substrate;
a LOCOS region surrounding an exposed portion of the first layer to define a junction region, wherein the junction region has a second conductivity; and
a metal layer disposed over the LOCOS region and the junction region.

13. The semiconductor diode of claim 12 wherein the first layer is an epitaxial layer.

14. The semiconductor diode of claim 12 wherein the LOCOS region includes a field oxide region.

15. The semiconductor diode of claim 12 wherein the first layer comprises an implantation layer formed in the semiconductor substrate.
